(19) United States
(12) Patent Application Publication
(10) Pub. No.: US 2026/0257438 A1
(43) Pub. Date: Sep. 3, 2026

(54) PREPARATION METHOD FOR DIFFRACTIVE OPTICAL WAVEGUIDE, DIFFRACTIVE OPTICAL WAVEGUIDE, AND IMPRINTING MASTER MOLD

(71) Applicant: SHANGHAI NORTH OCEAN TECHNOLOGIES CO., LTD, Shanghai (CN)

(72) Inventors: Hefeng Chen, Shanghai (CN); Dingqiang Chen, Shanghai (CN); Xuhong Guo, Shanghai (CN); Xinye Lou, Shanghai (CN); Kunpeng Li, Shanghai (CN)

(21) Appl. No.: 18/994,628

(22) PCT Filed: Aug. 15, 2023
(86) PCT No.: PCT/CN2023/113098

§ 371 Date: Jan. 15, 2025

(30) Foreign Application Priority Data
Aug. 31, 2022 (CN) 202211057795.0
Aug. 31, 2022 (CN) 202222303245.4

(51) Int. Cl. B29D 11/00

(52) U.S. Cl. CPC B29D 11/00721; B29K 2909/08

(57) ABSTRACT

A preparation method for a diffractive optical waveguide, and an imprinting master. The method comprises: providing a waveguide substrate; forming a graphical imprinting adhesive layer on one surface of the waveguide substrate; and performing first-stage etching on the waveguide substrate by using the graphical imprinting adhesive layer as a first mask, so as to form a coupling-in structure in a first region, forming a remaining graphical imprinting adhesive layer in a second region into a second mask, and etching the waveguide substrate by using the second mask as a mask, so as to form a coupling-out structure, wherein the depth of the coupling-out structure is greater than the depth of the coupling-in structure. In this way, the requirement of there being no obvious deviation in the relative positions between the coupling-in structure and the coupling-out structure is met while solving the problem of how to ensure the formation.

### TECHNICAL FIELD

The present disclosure relates to the field of diffractive optical waveguides, and in particular to a preparation method for a diffractive optical waveguide, a diffractive optical waveguide, and an imprinting master.

### BACKGROUND

Generally, diffractive optical waveguide can be divided into two parts according to functional regions: a coupling-in grating region and a coupling-out grating region. Based on the performance requirements of different functional regions, the coupling-in grating region and the coupling-out grating region usually adopt grating structures with different morphologies. For example, if the coupling-in region has performance requirements for efficient incoupling, a blazed grating is usually chosen in the coupling-in grating region, and if the coupling-out region has performance requirements for uniform outcoupling, a straight-tooth grating is usually chosen in the coupling-out grating region.

According to the design requirements of diffractive waveguide sheet, it is necessary to implement coupling-in and coupling-out structures with different depths on the target material, and the waveguide sheet is required to have good transmission efficiency and certain optical properties. In general, the preparation of a blazed grating is difficult and the process is complex, especially during the etching process. The longer the etching time (or the deeper the etching depth), the greater the effect on the surface morphology of the grating. If the blazed and straight-tooth gratings are formed by simultaneous etching, the etching of the straight-tooth grating is very limited due to the etching conditions for the blazed grating, especially when there is a difference in the grating depth between the blazed and straight-tooth gratings, the effect is more obvious. Moreover, since the depth of the straight-tooth grating is typically greater than that of the blazed grating, the performance of both gratings cannot be taken into account, resulting in a final diffractive optical waveguide that cannot achieve the expected effect.

In the prior art, the blazed and straight-tooth gratings are formed by separately etching through alignment, which easily leads to the deviation in the relative position between the coupling-in and coupling-out structures, thereby affecting the overall performance of the diffractive optical waveguide.

Therefore, developing a preparation process that can ensure the formation of coupling-in and coupling-out structures with different depths of the diffractive optical waveguide while meeting the requirement of there being no deviation in the relative position between the coupling-in and coupling-out structures, has become an urgent technical problem to be solved by those skilled in the art.

### CONTENT OF THE PRESENT INVENTION

The present disclosure provides a preparation method for a diffractive optical waveguide, a diffractive optical waveguide, and an imprinting master, so as to solve the problem of how to ensure that a coupling-in structure and a coupling-out structure with different depths are formed on a waveguide substrate while meeting the requirement of there being no obvious deviation in the relative position between the coupling-in structure and the coupling-out structure.

According to a first aspect of the present disclosure, provided is a preparation method for a diffractive optical waveguide, comprising:
providing a waveguide substrate;
forming a graphical imprinting adhesive layer on a surface of the waveguide substrate; wherein the graphical imprinting adhesive layer comprises a first graphical imprinting structure and a second graphical imprinting structure; the first graphical imprinting structure is formed in a first region of the surface, and the second graphical imprinting structure is formed in a second region of the surface; the second graphical imprinting structure has a thickness greater than that of the first graphical imprinting structure;
performing first-stage etching on the waveguide substrate by using the graphical imprinting adhesive layer as a first mask, so as to form a coupling-in structure on the waveguide substrate in the first region while maintaining a pattern of the second graphical imprinting structure on the waveguide substrate in the second region by a remaining graphical imprinting adhesive layer;
forming a second mask by using the remaining graphical imprinting adhesive layer, and performing second-stage etching on the waveguide substrate based on the second mask, so as to form a coupling-out structure in the second region;
wherein the second mask covers the coupling-in structure to protect the coupling-in structure from being etched during the second-stage etching; the coupling-in structure and the coupling-out structure differ in structural morphology, and the coupling-out structure has a depth greater than that of the coupling-in structure.

Optionally, the coupling-out structure has an equal etching depth, or different regions of the coupling-out structure are not equal in the etching depth.

Optionally, forming a second mask by using the remaining graphical imprinting adhesive layer, and performing second-stage etching on the waveguide substrate based on the second mask, so as to form a coupling-out structure in the second region comprises:
forming a first hard mask layer; wherein the first hard mask layer is formed on a surface of the waveguide substrate, and covers the coupling-in structure and the remaining graphical imprinting adhesive layer;
removing the remaining graphical imprinting adhesive layer and the first hard mask layer covering the remaining graphical imprinting adhesive layer to form the second mask;
performing second-stage etching on the waveguide substrate by using the second mask as a mask, so as to form a coupling-out structure in the second region.

Optionally, performing second-stage etching on the waveguide substrate by using the second mask as a mask, so as to form a coupling-out structure in the second region comprises: performing a first etching in the second-stage etching on the waveguide substrate by using the second mask as a mask, so as to form a coupling-out structure with an equal etching depth;
forming a photoresist layer N times; the photoresist layer formed each time covers a portion of the coupling-out structure, wherein N is an integer greater than or equal to 1;
etching, after each formation of the photoresist layer, a portion of the coupling-out structure that is not covered by the photoresist layer this time by using the photoresist layer formed this time and the remaining graphical imprinting adhesive as a mask, and forming N+1 different etched regions of the coupling-out structure after the Nth etching;
removing the photoresist and the second mask.

Optionally, forming a second mask by using the remaining graphical imprinting adhesive layer, and performing second-stage etching on the waveguide substrate based on the second mask, so as to form a coupling-out structure in the second region comprises:
forming a coupling-in protective layer on a surface of the coupling-in structure;
using the coupling-in protective layer and the remaining graphical imprinting adhesive layer as a second mask, and performing second-stage etching on the waveguide substrate based on the second mask, so as to form a coupling-out structure in the second region.

Optionally, forming a coupling-in protective layer on a surface of the coupling-in structure comprises:
dropping a predetermined amount of photoresist in a region where the coupling-in structure is located;
making the photoresist flow uniformly and cover the surface of the coupling-in structure under vacuum and negative pressure conditions;
curing the photoresist to form the photoresist layer.

Optionally, the coupling-in protective layer has a thickness greater than that of the remaining graphical imprinting adhesive layer.

Optionally, forming a graphical imprinting adhesive layer on a surface of the waveguide substrate specifically comprises:
providing an imprinting master; wherein the imprinting master is provided with a first master graphical structure and a second master graphical structure; wherein the first master graphical structure corresponds to the coupling-in structure; the second master graphical structure corresponds to the coupling-out structure;
coating the waveguide substrate with an imprinting adhesive;
imprinting the imprinting master onto the imprinting adhesive to form the graphical imprinting adhesive layer; wherein the graphical imprinting adhesive layer has a pattern corresponding to patterns of the first master graphical structure and the second master graphical structure;
separating the imprinting master from the graphical imprinting adhesive layer.

Optionally, imprinting the imprinting master onto the imprinting adhesive to form the graphical imprinting adhesive layer specifically comprises:
imprinting the imprinting master onto the imprinting adhesive;
curing the imprinting adhesive to form the graphical imprinting adhesive layer.

Optionally, the imprinting adhesive has a thickness adapted to the maximum depth of the patterns in the first master graphical structure and the second master graphical structure.

According to a second aspect of the present disclosure, provided is a diffractive optical waveguide, which is produced by the preparation method for the diffractive optical waveguide according to any one of the first aspect of the present disclosure.

According to a third aspect of the present disclosure, provided is an imprinting master, comprising:
a substrate;
a second master graphical structure and a first master graphical structure, which are formed on the substrate; wherein the substrate at the second master graphical structure has a thickness less than that of the substrate at the first master graphical structure;
the imprinting master is used to prepare a diffractive optical waveguide; the second master graphical structure has a pattern matching that of a coupling-out structure of the diffractive optical waveguide; the first master graphical structure has a pattern matching that of a coupling-in structure of the diffractive optical waveguide.

Optionally, the second master graphical structure comprises a number of groove structures or a number of protruding structures.

Optionally, the groove structure comprised in the second master graphical structure has a uniform depth.

Optionally, the second master graphical structure is a straight-tooth structure.

Optionally, the groove structure comprised in the second master graphical structure has a position consistent with that of a groove of the coupling-out structure of the diffractive optical waveguide; the groove structure comprised in the second master graphical structure has a width consistent with that of the groove of the coupling-out structure of the diffractive optical waveguide.

Optionally, the first master graphical structure is a blazed structure.

Optionally, the imprinting master has a material of SiO₂, Si, quartz glass, or high-refractive glass.

Optionally, the second master graphical structure and/or the first master graphical structure has a closed shape surrounded by a curve and/or straight line.

Optionally, the first master graphical structure has a pattern complementary to that of the coupling-in structure of the diffractive optical waveguide.

The present disclosure provides a preparation method for a diffractive optical waveguide utilizing a graphical imprinting adhesive layer formed on a waveguide substrate. Firstly, first-stage etching is performed on the waveguide substrate by using the graphical imprinting adhesive layer as a first mask to form a coupling-in structure in a first region, while a remaining graphical imprinting adhesive layer is formed in a second region. Secondly, the present disclosure provides a technical solution that creatively proposes: the remaining graphical imprinting adhesive layer is used to form a second mask to protect the coupling-in structure; and second-stage etching is performed on the waveguide substrate by using the second mask as a mask to form a coupling-out structure in the second region. The present disclosure can ultimately form a coupling-in structure and a coupling-out structure with different depths through these two sub-steps; and there is no obvious deviation in the relative position between the formed coupling-in structure and coupling-out structure from the preset relative position. It can be seen that the technical solution provided by the present disclosure solves the problem of how to ensure that a coupling-in structure and a coupling-out structure with different depths are formed on a waveguide substrate while meeting the requirement of there being no obvious deviation in the relative position between the coupling-in structure and the coupling-out structure. Moreover, the preparation method is suitable for mass production. In addition, the present disclosure provides an imprinting master which solves the problem of deviation in the relative position between the coupling-out structure and the coupling-in structure, by designing the imprinting master to comprise a second master graphical structure and a first master graphical structure, wherein the substrate at the second master graphical structure has a thickness less than that of the substrate at the first master graphical structure, such that when the imprinting master is used to produce a diffractive optical waveguide, patterns of the second master graphical structure and the first master graphical structure can be synchronously transferred to the diffractive optical waveguide, wherein the second master graphical structure and the first master graphical structure correspond to the coupling-in structure and the coupling-out structure, respectively. Moreover, the coupling-in structure and the coupling-out structure differ in adhesive thickness during the pattern transfer, allowing more freedom in designing the preparation method to form coupling-out and coupling-in structures with different morphologies, without affecting each other, thereby improving the overall performance of the diffractive optical waveguide.

### BRIEF DESCRIPTION OF THE DRAWINGS

In order to more clearly illustrate the technical solutions in the examples of the present disclosure or in the prior art, the drawings required to be used in the description of the examples or the prior art will be briefly introduced below. Obviously, the drawings described below are merely some examples of the present disclosure, and other drawings can also be obtained by those of ordinary skill in the art according to these drawings without any creative effort.

FIG. 1 is a schematic flow chart of a preparation method for a diffractive optical waveguide provided in an example of the present disclosure;

FIG. 2 is a schematic diagram of the structure of an imprinting master provided in a specific example of the present disclosure;

FIGS. 3 to 13 are schematic diagrams of the device structures produced at different process stages according to the preparation method for the diffractive optical waveguide provided in a specific example of the present disclosure;

FIGS. 14 to 15 are schematic diagrams of the device structures produced at different process stages according to the preparation method for the diffractive optical waveguide provided in another specific example of the present disclosure;

FIG. 16 is a schematic diagram of the structure of a vacuum vessel provided in an example of the present disclosure;

### EXPLANATION OF REFERENCE NUMERALS

101—waveguide substrate; 1011—coupling—in structure; 1012, 1013—coupling-out structure; 102—imprinting adhesive; 103—graphical imprinting adhesive layer; 1031—first graphical imprinting structure; 1032—second graphical imprinting structure; 104—imprinting master; 1041—substrate; 1042—second master graphical structure; 1043—first master graphical structure; 105—remaining graphical imprinting adhesive layer; 106—first hard mask layer; 107—second mask; 108—photoresist layer; 109—coupling-in protective layer; 110—vacuum vessel; 1101—vacuum vessel base; 11011—sealing ring; 11012—vacuum evacuation port; 1102—vacuum vessel cover.

### DETAILED DESCRIPTION OF THE PREFERRED EMBODIMENT

The technical solutions in the examples of the present disclosure will be clearly and completely described below in conjunction with the drawings in the examples of the present disclosure. Obviously, the described examples are merely some rather than all of the examples of the present disclosure. All other examples obtained by those of ordinary skill in the art based on the examples of the present disclosure without any creative effort shall fall within the scope of protection of the present disclosure.

In the specification, claims, and accompanying drawings of the present disclosure, the terms “first”, “second”, “third”, “fourth”, etc. (if present) are used for distinguishing between similar objects and not necessarily for describing a specific order or sequence. It should be understood that data used in this manner are interchangeable where appropriate, so that the examples of the present disclosure described herein can be implemented in a sequence other than those illustrated or described herein. In addition, the terms “include”, “comprise”, and any variants thereof are intended to cover a non-exclusive inclusion. For example, a process, method, system, product, or device that includes a series of steps or units is not necessarily limited to the steps or units that are explicitly listed, but may include other steps or units that are not explicitly listed or that are inherent to the process, method, product, or device.

Generally, diffractive optical waveguide can be divided into two parts according to functional regions: a coupling-in grating region and a coupling-out grating region. Based on the performance requirements of different functional regions, the coupling-in grating region and the coupling-out grating region usually adopt grating structures with different morphologies. For example, if the coupling-in region has performance requirements for efficient incoupling, a blazed grating is usually chosen in the coupling-in grating region, and if the coupling-out region has performance requirements for uniform outcoupling, a straight-tooth grating is usually chosen in the coupling-out grating region.

According to the design requirements of diffractive waveguide sheet, it is necessary to implement coupling-in and coupling-out structures with different depths on the target material, and the waveguide sheet is required to have good transmission efficiency and certain optical properties. In general, the preparation of a blazed grating is difficult and the process is complex, especially during the etching process. The longer the etching time (or the deeper the etching depth), the greater the effect on the surface morphology of the grating. If the blazed and straight-tooth gratings are formed by simultaneous etching, the etching of the straight-tooth grating is very limited due to the etching conditions for the blazed grating, especially when there is a difference in the grating depth between the blazed and straight-tooth gratings, the effect is more obvious. Moreover, since the depth of the straight-tooth grating is typically greater than that of the blazed grating, the performance of both gratings cannot be taken into account, resulting in a final diffractive optical waveguide that cannot achieve the expected effect.

In the prior art, the blazed and straight-tooth gratings are formed by separately etching through alignment, which easily leads to the deviation in the relative position between the coupling-in and coupling-out structures, thereby affecting the overall performance of the diffractive optical waveguide.

To this end, the present disclosure simultaneously forms patterns corresponding to a preset coupling-in structure and a preset coupling-out structure, respectively, on the surface of a waveguide substrate through a one-step imprinting process to meet the requirement of there being essentially no deviation in the relative position between the coupling-in and coupling-out structures. Meanwhile, by skillfully setting up a mask and performing etching in two stages to form a coupling-in structure and a coupling-out structure, respectively, coupling-in and coupling-out structures with different depths can be achieved.

Further, in the present disclosure, while performing first-stage etching to form the coupling-in structure, the remaining adhesive layer at the position of the preset coupling-out structure is controlled such that it still retains a pattern reflecting the coupling-out structure. The remaining adhesive layer is then used to form a second mask, based on which second-stage etching is performed on the waveguide substrate to form the coupling-out structure. Moreover, the second mask covers the coupling-in structure, ensuring that the morphology of the coupling-in structure is not affected during the second-stage etching. It can be seen that the use of the method provided by the present disclosure can ensure the formation of coupling-in and coupling-out structures with different depths of the diffractive optical waveguide while meeting the requirement of there being no deviation in the relative position between the coupling-in and coupling-out structures. Moreover, the method is suitable for mass production.

Further, in the present disclosure, a hard mask is skillfully formed on the waveguide substrate using a dissolution process, so as to etch the waveguide substrate in the coupling-out region by using the hard mask as a mask to form a coupling-out structure with a depth different from that of the coupling-in structure in the coupling-out region. Moreover, compared to the prior art, there is no obvious deviation in the relative position between the coupling-out and coupling-in structures formed by the method. Furthermore, etching the coupling-out structure by using the hard mask as a mask also enables different etching depths in different regions.

Moreover, in the present disclosure, a similar effect can also be achieved by protecting the coupling-in structure by coating photoresist on the top of the already formed coupling-in structure, and etching the waveguide substrate in the coupling-out region by using the remaining imprint-formed imprinting adhesive as a mask to form the coupling-out structure. In addition, conventional imprinting masters generally have only one morphological structure, and the diffractive optical waveguide prepared by the imprinting master generally involves a one-step imprinting process. In other words, when the grating structure of the imprinting master and the grating structure of the diffractive optical waveguide fit face to face, the protrusions of the grating structure of the imprinting master fill the grooves of the grating structure of the diffractive optical waveguide, achieving a tight fit. Similarly, the protrusions of the grating structure of the diffractive optical waveguide fill the grooves of the grating structure of the imprinting master, achieving a tight fit. Thus, the structure of the imprinting master in the prior art is unable to prepare coupling-out and coupling-in structures with different morphologies, which is not conducive to improving the performance of the diffractive optical waveguide. The existing method of forming coupling-out and coupling-in structures with different morphologies by separately etching through alignment easily leads to the deviation in the relative position between the coupling-in and coupling-out structures, which also affects the overall performance of the diffractive optical waveguide.

To this end, the present disclosure proposes a new imprinting master structure, wherein the imprinting master is designed such that a second master graphical structure and a first master graphical structure are formed on the substrate, and the relative position between the two are fixed, so that in the process of preparing a diffractive optical waveguide using the imprinting master, by transferring the pattern of the imprinting master to the imprinting adhesive to form a graphical imprinting adhesive, the patterns of the second master graphical structure and the first master graphical structure can be transferred to the adhesive layer at one time, which solves the problem of deviation in the relative position between the coupling-out structure and the coupling-in structure. Moreover, the substrate at the second master graphical structure has a thickness less than that of the substrate at the first master graphical structure. In this way, by etching the waveguide substrate using the graphical imprinting adhesive as a first mask and etching the first master graphical structure with a larger thickness onto the waveguide substrate, the remaining graphical imprinting adhesive at the corresponding position of the second master graphical structure with a smaller thickness still retains the pattern of the graphical imprinting adhesive, which provides more freedom in designing how to protect the coupling-in portion that has already been formed (a portion corresponding to the second master graphical structure) and continue to form the coupling-out portion to be formed (a portion corresponding to the first master graphical structure). As a result, it is possible to etch coupling-out and coupling-in structures with different morphologies, both of which can achieve the expected effect.

It can be seen that the technical solutions provided by the present disclosure can solve the problem of how to eliminate the deviation in the relative position between the coupling-out and coupling-in structures while etching the coupling-out and coupling-in structures with different morphologies, thereby improving the overall performance of the diffractive optical waveguide.

The technical solutions of the present disclosure are described in detail below by way of specific examples. The following specific examples can be combined with each other, and the same or similar concepts or processes may not be repeated in some examples.

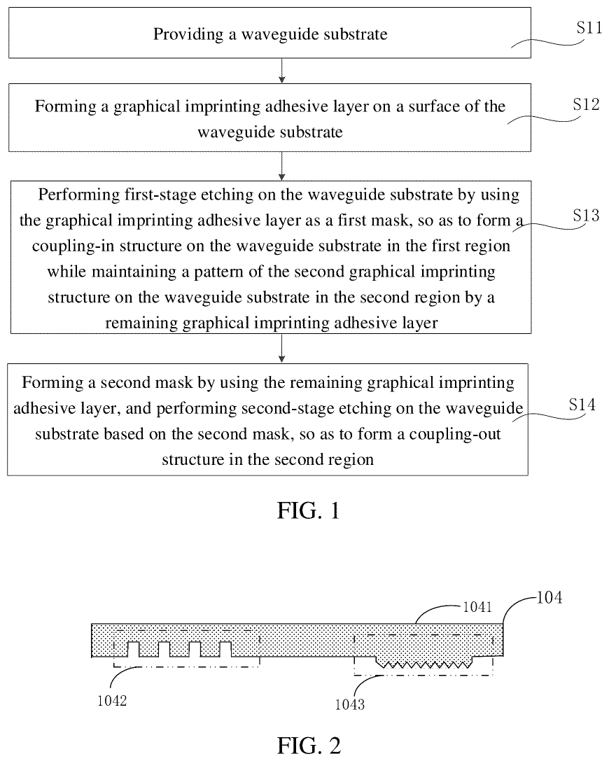

According to an example of the present disclosure, provided is a preparation method for a diffractive optical waveguide, whose flow chart is shown in FIG. 1. The method comprises:
S11: providing a waveguide substrate 101;
S12: forming a graphical imprinting adhesive layer on a surface of the waveguide substrate 101; the graphical imprinting adhesive layer comprises a first graphical imprinting structure 1031 and a second graphical imprinting structure 1032; the first graphical imprinting structure 1031 is formed in a first region of the surface, and the second graphical imprinting structure 1032 is formed in a second region of the surface; the second graphical imprinting structure 1032 has a thickness greater than that of the first graphical imprinting structure 1031; the device structure after formation of the graphical imprinting adhesive layer is shown in FIG. 4.

In an example, the step S12 of forming a graphical imprinting adhesive layer on a surface of the waveguide substrate 101 specifically comprises the following steps S121 to S124:

S121: providing an imprinting master 104; the imprinting master is provided with a first master graphical structure 1043 and a second master graphical structure 1042; wherein the first master graphical structure 1043 corresponds to a coupling-in structure 1011; the second master graphical structure 1042 corresponds to a coupling-out structure 1012; the structure of the imprinting master 104 is shown as 104 in FIG. 2 or FIG. 5.

Specifically, the first master graphical structure 1043 corresponds to the coupling-in structure 1011, and the second master graphical structure 1042 corresponds to the coupling-out structure 1012, including: the first master graphical structure 1043 has a pattern corresponding to that of the preset coupling-in structure 1011; the second master graphical structure 1042 has a pattern corresponding to that of the preset coupling-out structure 1012. Herein, the pattern correspondence may be either pattern consistency or pattern complementarity.

In addition, the first master graphical structure 1043 corresponding to the coupling-in structure 1011 may further include that the first master graphical structure 1043 has a pattern depth consistent with that of the coupling-in structure 1011.

In a preferred embodiment, the first master graphical structure 1043 has a thickness of 100 to 500 nm, and the second master graphical structure 1042 has a thickness of 100 to 300 nm.

In an embodiment, the imprinting master 104 has a material of SiO₂, and the material may also be SiO₂, TiO₂, Nb₂O₅, high-refractive glass, etc.; it is certain that the material may also be any other material, and the present disclosure is not limited thereto.

In an embodiment, the first master graphical structure 1043 and/or the second master graphical structure 1042 has a cross-section of a quadrilateral or a triangle; in other embodiments, the cross-section may also be any other shape that can achieve the purpose of the present disclosure, and the present disclosure is not limited thereto; any implementation is within the scope of protection of the present disclosure.

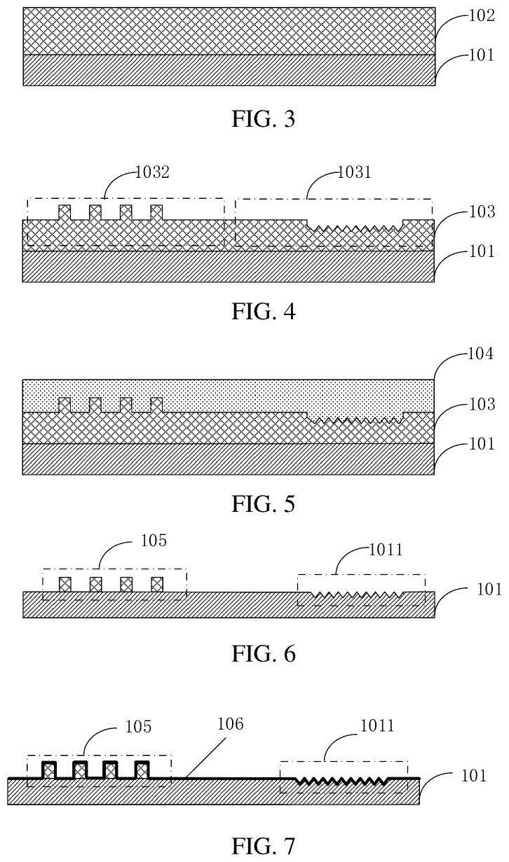

S122: coating the waveguide substrate 101 with an imprinting adhesive 102, as shown in FIG. 3. Preferably, the imprinting adhesive 102 should have good fluidity and photosensitivity, as well as good resistance to dry etching; taking into account that the commonly used semiconductor etching gas in dry etching includes F-based and Cl-based gases, the imprinting adhesive 102 can be selected based on these etching gases when considering the resistance to dry etching.

In an example, the coated imprinting adhesive 102 has a thickness adapted to the maximum thickness of the pattern in the first master graphical structure 1043 and the second master graphical structure 1042; “adapted to” means that the thickness of the imprinting adhesive 102 is greater than or equal to the maximum thickness of the pattern in the first master graphical structure 1043 and the second master graphical structure 1042, so as to provide the imprinting adhesive 102 with sufficient thickness, such that the finally formed first graphical imprinting structure 1031 and second graphical imprinting structure 1032 have a depth matching the thickness of the first master graphical structure 1043 and the second master graphical structure 1042. In practice, the imprinting adhesive 102 typically has a thickness of 100 to 1000 nm.

In an embodiment, the method used for coating the waveguide substrate 101 with the imprinting adhesive 102 is a spin coating method or a spray coating method; in other embodiments, the method may also be any other implementation, and the present disclosure is not limited thereto.

S123: imprinting the imprinting master 104 onto the imprinting adhesive 102 to form a graphical imprinting adhesive layer 103; wherein the graphical imprinting adhesive layer 103 has a pattern corresponding to patterns of the first master graphical structure 1043 and the second master graphical structure 1042; the device structure after imprinting the imprinting master 104 onto the imprinting adhesive 102 is shown in FIG. 5.

In an example, the step S123 of imprinting the imprinting master 104 onto the imprinting adhesive 102 to form a graphical imprinting adhesive layer 103 specifically comprises the following steps S1231 to S1232:

S1231: imprinting the imprinting master 104 onto the imprinting adhesive 102.

In an embodiment, the method used for imprinting the imprinting master 104 onto the imprinting adhesive 102 is an integrated nanoimprinting process. The integrated nanoimprinting process is used to fully contact the imprinting master 104 with the imprinting adhesive 102, ensuring that the structure of the imprinting master 104 is completely transferred to the imprinting adhesive, thereby forming the graphical imprinting adhesive layer 103 (as shown in FIG. 5).

S1232: curing the imprinting adhesive 102 to form the graphical imprinting adhesive layer 103.

In an example, the method used for curing the imprinting adhesive 102 is UV light exposure or thermal curing technology; in other examples, the method may also be any other implementation, and the present disclosure is not limited thereto.

S124: separating the imprinting master 104 from the graphical imprinting adhesive layer 103. The device structure after separating the imprinting master 104 from the graphical imprinting adhesive layer 103 is shown in FIG. 4.

In an embodiment, the process used for separating the imprinting master 104 from the graphical imprinting adhesive layer 103 is a demoulding process; in other embodiments, the process may also be any other implementation, and the present disclosure is not limited thereto. After demoulding, structural information corresponding to the master is obtained on the graphical imprinting adhesive layer 103, which can be used as a mask for subsequent dry etching.

S13: performing first-stage etching on the waveguide substrate 101 by using the graphical imprinting adhesive layer 103 as a first mask, so as to form a coupling-in structure 1011 on the waveguide substrate 101 in the first region while maintaining a pattern of the second graphical imprinting structure 1032 on the waveguide substrate 101 in the second region by the remaining graphical imprinting adhesive 102; the device structure after performing step S13 is shown in FIG. 6.

In an embodiment, first-stage etching is performed using dry etching; wherein the etching gas used is a commonly used semiconductor etching gas, such as F-based and Cl-based gases.

S14: forming a second mask 107 by using a remaining graphical imprinting adhesive layer 105, and performing second-stage etching on the waveguide substrate 101 based on the second mask 107, so as to form a coupling-out structure 1012 or 1013 in the second region. The device after formation of the coupling-out structure 1012 or 1013 is shown in FIG. 10 or 13 (it should be noted that the device structure in FIG. 9 is a schematic diagram of the device structure prior to removal of the second mask).

Herein, the second mask 107 covers the coupling-in structure 1011 to protect the coupling-in structure 1011 from being etched during the second-stage etching; the coupling-in structure 1011 and the coupling-out structure 1012 or 1013 differ in structural morphology, and the coupling-out structure 1012 or 1013 has a depth greater than that of the coupling-in structure 1011.

Herein, the coupling-out structure 1012 has an equal etching depth, and different regions of the coupling-out structure 1013 are not equal in the etching depth. In the present disclosure, based on the etching resistance of hard mask materials compared to photoresist materials, the hard mask is used in conjunction with the photoresist mask to enable a coupling-out structure with different etching depths in different regions.

In an embodiment, the coupling-in structure 1011 and/or the coupling-out structure 1012 or 1013 has a cross-section of a quadrilateral or a triangle; in other embodiments, the cross-section may also be any other shape that can achieve the purpose of the present disclosure, and the present disclosure is not limited thereto; any implementation is within the scope of protection of the present disclosure.

The present disclosure provides a preparation method for a diffractive optical waveguide by forming the graphical imprinting adhesive layer 103 on the waveguide substrate 101, followed by two sub-steps: first step: forming the coupling-in structure 1011 in the first region, specifically comprising: performing first-stage etching on the waveguide substrate 101 in the first region by using the graphical imprinting adhesive layer 103 as a first mask, and controlling the etching time to enable the etching to form the coupling-in structure 1011 while forming a remaining graphical imprinting adhesive in the second region; second step: forming a second mask by using the remaining graphical imprinting adhesive layer 105, so as to protect the coupling-in structure 1011 by using the second mask as a mask, and etching the waveguide substrate 101 in the second region to form the coupling-out structure 1012 or 1013.

Due to the technical solution provided by the present disclosure, after the coupling-in structure 1011 and the remaining graphical imprinting adhesive layer 105 are formed in the first step, a second mask is formed by using the remaining graphical imprinting adhesive layer 105, and second-stage etching is performed on the waveguide substrate 101 in the second region by using the second mask as a mask to form the coupling-out structure 1012 or 1013. It can be seen that under the protection of the second mask, when there is a difference in the etching depth of the coupling-out structure 1012 or 1013 and the coupling-in structure 1011, especially when the depth of the coupling-out structure 1012 or 1013 needs to be greater than the depth of the coupling-in structure 1011, the etching of the grating structure with a larger depth will not be limited by the grating structure with a smaller etching depth. In this way, the etching depths of the coupling-in structure 1011 and the coupling-out structure 1012 or 1013 with different depths can be balanced, thereby achieving balanced performance for both the coupling-in structure 1011 and the coupling-out structure 1012 or 1013. Moreover, the depth of the finally formed coupling-out structure 1012 or 1013 is allowed to be different from the depth of the coupling-in structure 1011, while there is no obvious deviation in the relative position between the coupling-in structure 1011 and the coupling-out structure 1012 or 1013 from the preset relative position.

Thus, the technical solution provided by the present disclosure solves the problem of how to ensure that the coupling-in structure 1011 and the coupling-out structure 1012 or 1013 with different depths are formed on the waveguide substrate 101 while meeting the requirement of there being no obvious deviation in the relative position between the coupling-in structure 1011 and the coupling-out structure 1012 or 1013, thereby achieving the technical effect of improving the overall performance of the diffractive optical waveguide. Moreover, the technical solution is suitable for mass production.

Referring to FIGS. 1 to 13, the specific steps of performing second-stage etching on the waveguide substrate 101 based on the second mask 107, so as to form a coupling-out structure 1012 or 1013 in the second region are described below in two specific examples:

In a specific example, the step S14 of forming a second mask 107 by using a remaining graphical imprinting adhesive layer 105, and performing second-stage etching on the waveguide substrate 101 based on the second mask 107, so as to form a coupling-out structure 1012 or 1013 specifically comprises the following steps S141 to S143:

S141: forming a first hard mask layer 106; the first hard mask layer 106 is formed on a surface of the waveguide substrate 101, and covers the coupling-in structure 1011 and the remaining graphical imprinting adhesive layer 105.

Specifically, the first hard mask layer 106 has a material of Cr, Al, SiO₂, or Si₃N₄; it is certain that the material may also be any other material; any implementation of the first hard mask layer 106 that can achieve the purpose of the present disclosure is within the scope of protection of the present disclosure, and the present disclosure is not limited thereto. Preferably, in an embodiment, the first hard mask layer 106 is an Al metal film; the Al metal film can well cover the surface of the waveguide substrate 101, and avoid deposition as much as possible on the sidewalls of the remaining graphical imprinting adhesive layer 105; it can avoid defects in the shape of the etched coupling-out structure 1012 or 1013, so as to prepare the coupling-out structure 1012 or 1013 with desirable performance; the device structure after formation of the first hard mask layer 106 is shown in FIG. 7;
wherein the first hard mask layer 106 has an etching rate in dry etching much less than that of the imprinting adhesive 102;
in an embodiment, the semiconductor film forming technology used for forming the first hard mask layer 106 is a PVD coating process, specifically a sputtering or evaporation method;
in an embodiment, the first hard mask layer 106 has preferably a thickness of 50 nm in order to effectively protect the coupling-in structure 1011;

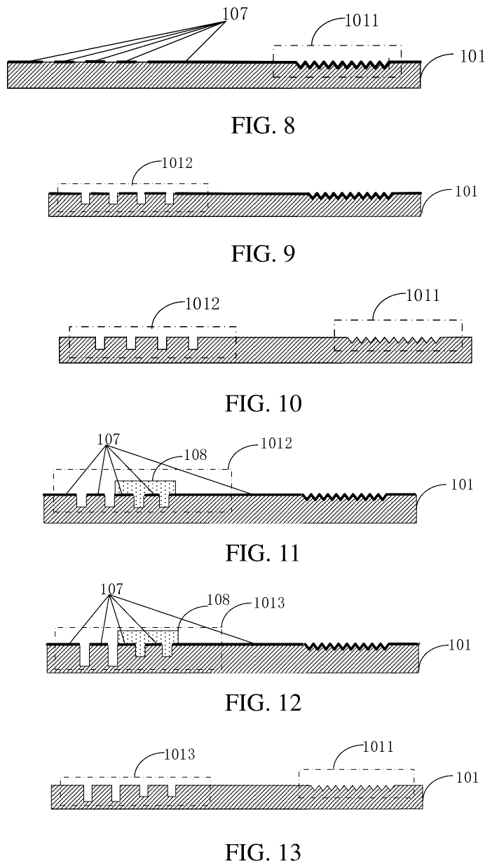

S142: removing the remaining graphical imprinting adhesive layer 105 and the first hard mask layer 106 covering the remaining graphical imprinting adhesive layer 105 to form the second mask 107 to expose a substrate 1041 of the coupling-out structure 1012; using the remaining hard mask layer as the second mask 107; the device structure after formation of the second mask 107 is shown in FIG. 8;
in an embodiment, the process used for removing the remaining graphical imprinting adhesive layer 105 is a dissolution process; it is certain that the process may also be any other implementation; any implementation of removing the remaining graphical imprinting adhesive layer 105 that can achieve the purpose of the present disclosure is within the scope of protection of the present disclosure, and the present disclosure is not limited thereto.

The process flow of the dissolution process specifically includes: firstly, placing the device obtained in step S141, which includes the remaining graphical imprinting adhesive layer 105, into an ultrasonic tank; secondly, adding an organic solvent with high polarity into the ultrasonic tank; thirdly, turning on ultrasound to assist the organic solvent in swelling the remaining graphical imprinting adhesive layer 105 until it is completely stripped and removed; finally, using a spin dryer to clean and dry the device obtained in step S141, which includes the remaining graphical imprinting adhesive layer 105, to obtain the device after removal of the remaining graphical imprinting adhesive layer 105 in step S142;
wherein the organic solvent needs to satisfy the condition that it basically has no corrosive and swelling effects on the hard mask material; in a specific embodiment, the organic solvent is typically acetone or dimethyl sulfoxide;

S143: performing second-stage etching on the waveguide substrate 101 by using the second mask 107 as a mask, so as to form the coupling-out structure 1012 or 1013 in the second region; the device structure after formation of the coupling-out structure 1012 or 1013 is shown in FIG. 10 or 13.

In an embodiment, the method used for performing the second-stage etching is a dry etching method. In the second-stage etching, by performing a single etching step, the coupling-out structure 1012 with an equal etching depth can be etched. By performing multiple etching steps, the coupling-out structure 1013 with different etching depths in different regions can be etched.

Herein, each region of etching depth within the coupling-out structure 1013 may include a number of grating units with the same etching depth within the region. The number of grating units is not limited by the present disclosure.

In an example, the step S143 of performing second-stage etching on the waveguide substrate 101 by using the second mask 107 as a mask, so as to form the coupling-out structure 1012 in the second region comprises:
performing a first etching in the second-stage etching on the waveguide substrate 101 by using the second mask 107 as a mask until a target depth is reached; removing the remaining hard mask layer from the etched waveguide substrate 101 to form the coupling-out structure 1012 with an equal etching depth. This results in a final diffractive optical waveguide structure with coupling-in and coupling-out structures with different morphologies and no positional deviation. Moreover, the morphologies of the resulting coupling-in and coupling-out structures can also reach the expected level.

In an example, the step S143 of performing second-stage etching on the waveguide substrate 101 by using the second mask 107 as a mask, so as to form the coupling-out structure 1013 in the second region comprises:
performing a first etching in the second-stage etching on the waveguide substrate 101 by using the second mask 107 as a mask, so as to form the coupling-out structure 1012 with an equal etching depth;
forming a photoresist layer 108 N times; the photoresist layer 108 formed each time covers a portion of the coupling-out structure, wherein N is an integer greater than or equal to 1, as shown in FIG. 11;
after each formation of the photoresist layer 108, etching a portion of the coupling-out structure on the waveguide substrate 101 that is not covered by the photoresist layer 108 this time by using the photoresist layer 108 formed this time and the remaining graphical imprinting adhesive of the second mask 107 as a mask, as shown in FIG. 12; forming N+1 different etched regions of the coupling-out structure 1013 after the Nth etching; removing the photoresist and the second mask 107, as shown in FIG. 13.

Herein, the material of the second mask 107 is referred to the material of the first hard mask layer 106 described above, which is not repeated herein.

In the specific example described above, after performing first-stage etching on the waveguide substrate 101 to form the coupling-in structure 1011, while forming the remaining graphical imprinting adhesive layer 105 on the waveguide substrate 101 in the second region, the first hard mask layer 106 is skillfully formed on both the surface of the waveguide substrate 101 and the surface of the remaining graphical imprinting adhesive layer 105, and then the remaining graphical imprinting adhesive layer 105 is removed using a dissolution process. Since the second hard mask layer can protect the coupling-in structure 1011, the desired coupling-out structure 1012 or 1013 can be etched without affecting the coupling-in structure 1011 in the first region during the etching of the coupling-out structure 1012 or 1013 in the second region, thereby achieving the etching of the coupling-in structure 1011 and the coupling-out structure 1012 or 1013 in steps. It ensures the formation of the coupling-in structure 1011 and the coupling-out structure 1012 or 1013 with different depths of the diffractive optical waveguide while meeting the requirement of there being no deviation in the relative position between the coupling-in structure 1011 and the coupling-out structure 1012 or 1013. Moreover, the method is suitable for mass production.

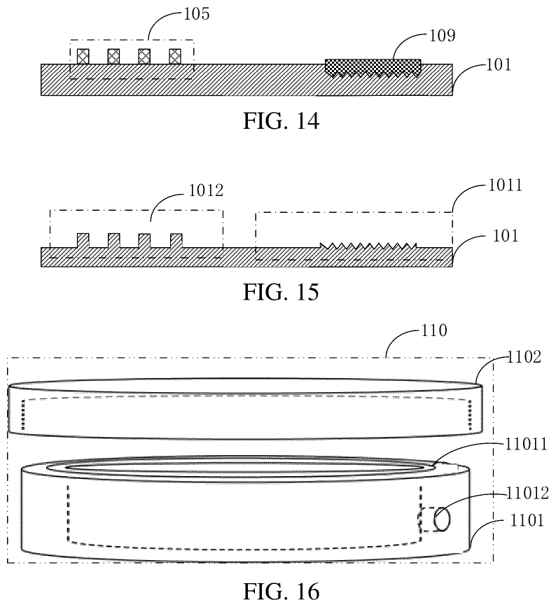

Referring to FIGS. 1, 3 to 6, and 14 to 16, according to another specific example of the present disclosure, the step S14 of forming a second mask 107 by using a remaining graphical imprinting adhesive layer 105, and performing second-stage etching on the waveguide substrate 101 based on the second mask 107, so as to form a coupling-out structure 1012 specifically comprises the following steps S141 to S142:
step S141: forming a coupling-in protective layer 109 on the surface of the coupling-in structure 1011; in a specific embodiment, the coupling-in protective layer 109 is a photoresist layer 108; the device structure after formation of the coupling-in protective layer 109 is shown in FIG. 14;
in an example, the step S141 of forming a coupling-in protective layer 109 on the surface of the coupling-in structure 1011 specifically comprises the following steps S1411 to S1413:
step S1411: dropping a predetermined amount of photoresist in a region where the coupling-in structure 1011 is located;
step S1412: making the photoresist flow uniformly and cover the surface of the coupling-in structure 1011 under vacuum and negative pressure conditions;
step S1413: curing the photoresist to form the photoresist layer 108.

In an embodiment, when the formed coupling-in protective layer 109 is a photoresist layer 108, the method used in forming the coupling protective layer 109 is a photoresist vacuum coating method;
performing step S141 by using the photoresist vacuum coating method to form the coupling protective layer 109 specifically comprises:
first, dropping a suitable amount of photoresist on the top of the coupling-in structure 1011; the amount of photoresist typically ranges from 0.1 to 10 mL, depending on the size of the coupling-in structure 1011, which is placed horizontally for several minutes;
next, placing the entire device structure into a dedicated horizontally placed vacuum vessel 110, and applying a certain amount of negative pressure inside the vacuum vessel 110 to allow the photoresist to flow uniformly onto the top of the coupling-in structure 1011 without producing any bubbles throughout the entire process; specifically comprising: placing the target material substrate with the dropped photoresist horizontally into the vacuum vessel 110, performing first vacuum evacuation with a vacuum pressure of less than 100 Pa, allowing the vessel to stand horizontally for several minutes, and slowly introducing an inert gas (such as GN₂ or Ar) to restore to atmospheric pressure; performing second vacuum evacuation with a vacuum pressure of less than 100 Pa, allowing the vessel to stand horizontally for several minutes, and slowly introducing an inert gas (such as GN₂ or Ar) to restore to atmospheric pressure; performing third vacuum evacuation with a vacuum pressure of less than 100 Pa, allowing the vessel to stand horizontally for several minutes, and slowly introducing an inert gas (such as GN₂ or Ar) to restore to atmospheric pressure; generally speaking, after three times of vacuum evacuation, the protective photoresist in the region where the coupling-in structure 1011 is located will be free of bubbles, and if there are still bubbles, vacuum evacuation can be performed again until there are no bubbles;
finally, taking out the device and placing it horizontally into an oven or on a hot plate for baking until the photoresist is cured;
the vacuum vessel 110 is made of organic glass, and specifically includes: a vacuum vessel cover 1102, a vacuum vessel base 1101, a sealing ring 11011, and a vacuum evacuation port 11012; the structure of the vacuum vessel 110 is shown in FIG. 16.

Step S142: using the coupling-in protective layer 109 and the remaining graphical imprinting adhesive layer 105 as a second mask 107, and performing second-stage etching on the waveguide substrate 101 based on the second mask 107, so as to form a coupling-out structure 1012 in the second region;
when the coupling-in protective layer 109 is a photoresist layer 108, the coupling protective layer 109 has preferably a thickness greater than that of the remaining graphical imprinting adhesive layer 105; typically, the difference in thickness between the two is controlled to be 1 to 2 μm.

The step S14 further comprises step S143 following step S142: removing the remaining coupling protective layer 109 to form a diffractive optical waveguide; the device structure after formation of the diffractive optical waveguide is shown in FIG. 15.

In another example, when etching the coupling-out structure using the hard mask 107 as a mask, the coupling-in protective layer 109 can also be formed on the surface of the coupling-in structure 1011 in the same steps as S1411 to S1413.

Secondly, according to an example of the present disclosure, also provided is a diffractive optical waveguide, which is produced by the preparation method for the diffractive optical waveguide according to any one of the aforementioned examples of the present disclosure.

Thirdly, according to an example of the present disclosure, also provided is an AR device comprising the diffractive optical waveguide provided in the aforementioned example of the present disclosure.

Referring to FIGS. 2, 4 to 10, and 13, according to an example of the present disclosure, provided is an imprinting master 104; it should be noted that FIG. 2 is only the structure of the imprinting master 104 provided in a specific example of the present disclosure, but the present disclosure is not limited thereto; any imprinting master structure within the scope of description of the present disclosure that can achieve the purpose of the present disclosure is within the scope of protection of the present disclosure; as shown in FIG. 2, the imprinting master 104 comprises:
a substrate 1041; the substrate 1041 may typically have a material of SiO₂, Si, quartz glass, or high-refractive glass; it should be noted that the material of the substrate is not limited thereto;
a second master graphical structure 1042 and a first master graphical structure 1043, which are formed on the substrate 1041; wherein the substrate 1041 at the second master graphical structure 1042 has a thickness less than that of the substrate 1041 at the first master graphical structure 1043; in a specific example, the application of the imprinting master 104 is shown in FIG. 2, wherein the second master graphical structure 1042 and the first master graphical structure 1043 have different patterns.

It can be seen that the substrate 1041 at the second master graphical structure 1042 has a thickness less than that of the substrate 1041 at the first master graphical structure 1043; accordingly, in conjunction with FIGS. 4 to 10, it can be seen that in the graphical imprinting adhesive layer 103 formed with the imprinting master 104 provided by the present disclosure, the imprinting adhesive formed by imprinting at the second master graphical structure 1042 has a thickness greater than that of the imprinting adhesive formed by imprinting at the first master graphical structure 1043; such that when the coupling-in structure 1012 is etched on the waveguide substrate 101 by using the graphical imprinting adhesive layer 103 as a first mask, the remaining imprinting adhesive on the coupling-out structure 1012 still retains the pattern of the graphical imprinting adhesive layer 103, and then the coupling-out structure 1012 is etched by using the second mask 107; the formed coupling-out structure 1012 has an etching depth greater than that of the coupling-in structure 1011; it can be seen that the coupling-out structure 1012 and the coupling-in structure 1011 with different morphologies can be etched by using the diffractive optical waveguide produced by the imprinting master 104 provided by the present disclosure, that is, the etching depths of the coupling-in structure 1011 and the coupling-out structure 1012 are balanced while eliminating the problem of deviation in the relative position between the coupling-in and coupling-out structures produced by the imprinting master 104 in the prior art, thereby improving the overall performance of the diffractive optical waveguide.

The technical solution provided by the present disclosure solves the problem of deviation in the relative position between the coupling-out structure and the coupling-in structure, by designing the imprinting master to comprise a second master graphical structure and a first master graphical structure, wherein the substrate at the second master graphical structure has a thickness less than that of the substrate at the first master graphical structure, such that when the imprinting master is used to produce a diffractive optical waveguide, patterns of the second master graphical structure and the first master graphical structure can be synchronously transferred to the diffractive optical waveguide, wherein the second master graphical structure and the first master graphical structure correspond to the coupling-in structure and the coupling-out structure, respectively. Moreover, the coupling-in structure and the coupling-out structure differ in adhesive thickness during the pattern transfer, allowing more freedom in designing the preparation method to form coupling-out and coupling-in structures with different morphologies, without affecting each other, thereby improving the overall performance of the diffractive optical waveguide.

In an example, the second master graphical structure 1042 and/or the first master graphical structure 1043 has a closed shape surrounded by a curve and/or straight line. Herein, the shape refers to a shape of the region where the second master graphical structure 1042 and/or the first master graphical structure 1043 are located.

In an example, the imprinting master 104 is used to prepare a diffractive optical waveguide, and the second master graphical structure 1042 has a pattern matching that of the coupling-out structure 1012 of the diffractive optical waveguide.

Implementably, the second master graphical structure 1042 has a pattern matching that of the coupling-out structure 1012 of the diffractive optical waveguide, which may be that the second master graphical structure 1042 has a pattern complementary to that of the coupling-out structure 1012 of the diffractive optical waveguide; or the second master graphical structure 1042 has a pattern consistent with that of the coupling-out structure 1012 of the diffractive optical waveguide, that is, the position of the groove of the second master graphical structure 1042 is consistent with the position and width of the groove of the coupling-out structure 1012 of the diffractive optical waveguide.

In an example, the second master graphical structure 1042 is a straight-tooth structure that is recessed relative to the surface of the substrate 1041. The coupling-out structure of the diffractive optical waveguide is also a straight-tooth structure, which may specifically be a structure that protrudes relative to the surface of the diffractive optical waveguide or a structure that is recessed relative to the surface of the diffractive optical waveguide.

In an example, the first master graphical structure 1043 has a pattern matching that of the coupling-in structure 1011 of the diffractive optical waveguide. Implementably, the first master graphical structure 1043 has a pattern complementary to that of the coupling-in structure 1011 of the diffractive optical waveguide.

In an example, the first master graphical structure 1043 is a blazed structure; the coupling-in structure 1011 of the diffractive optical waveguide is a blazed structure; the two blazed structures are complementary.

In an example, the second master graphical structure 1042 comprises a number of groove structures or a number of protruding structures; FIG. 2 shows the second master graphical structure 1042 with groove structures.

When the second master graphical structure 1042 comprises a number of groove structures, in an example, the width of the groove structure comprised in the second master graphical structure 1042 is designed to be consistent with that of the groove of the coupling-out structure 1012 of the diffractive optical waveguide.

The preparation method for the imprinting master 104 provided by the present disclosure specifically comprises the following steps:
Step 1: forming an imprinting master 104 using a micro-nano patterning process or dry etching technique.
Step 2: cleaning the imprinting master 104.

It specifically comprises: first step: immersing the imprinting master 104 into a cleaning solution, heating it to 125° C., and soaking it for 10 minutes; second step: preparing a solution of NH₄OH:H₂O₂:H₂O, heating it to 70° C., and soaking it for 10 minutes; thus finally forming the imprinting master 104; in a specific embodiment, the cleaning solution used for cleaning the imprinting master 104 is a solution of H₂SO₄:H₂O₂:H₂O.

In an example, the size of the groove structure comprised in the second master graphical structure 1042 is designed to be consistent with the size of the groove of the preset coupling-out structure 1012 of the diffractive optical waveguide, and the position of the groove is also consistent; the size of the pattern of the remaining graphical imprinting adhesive layer 103 after first-stage etching is consistent with the size of the groove structure of the second master graphical structure 1042; when the remaining graphical imprinting adhesive layer 105 on the surface of the coupling-out structure 1012 and the hard mask layer on the surface of the remaining graphical imprinting adhesive layer 105 are removed using a dissolution process, the size of the exposed substrate 1041 of the coupling-out structure 1012 is consistent with the size of the groove structure comprised in the second master graphical structure 1042 on the imprinting master 104, and their positions are also consistent; the size of the groove of the coupling-out structure 1012 etched on the waveguide substrate 101 by using the hard mask layer as the second mask 107 is consistent with the size of the groove of the preset coupling-out structure 1012; the size of the groove structure comprised in the second master graphical structure 1042 is designed to be consistent with that of the groove of the coupling-out structure 1012 of the diffractive optical waveguide, which means that the width of the groove structure is consistent with the width of the groove of the coupling-out structure 1012.

In an example, the groove structure comprised in the second master graphical structure 1042 has a uniform depth.

The imprinting master 104 provided by the present disclosure can not only be used to prepare a diffractive optical waveguide with a coupling-out structure 1012 with the same etching depth, as shown in FIG. 10; but also be used to prepare a diffractive optical waveguide with a coupling-out structure 1012 with different etching depths, as shown in FIG. 13. Specifically, as described in the previous sections of the present disclosure, on the basis of the coupling-out structure 1012 of the diffractive optical waveguide with the same etching depth, localized positions of the coupling-out structure 1012 with a larger depth are continued to be etched using the photoresist as a mask to form a coupling-out structure 1013 of the diffractive optical waveguide with different etching depths.

It can be seen that the imprinting master 104 provided by the present disclosure can not only be used to prepare coupling-out structures 1012 and coupling-in structures 1011 with different morphologies, but also be used to prepare coupling-out structures 1012 and 1013 with different etching depths. Therefore, the imprinting master 104 provided by the present disclosure is widely used and easy for mass production of optical waveguide substrates 101.

Finally, it should be noted that the aforementioned examples are merely used for illustrating rather than limiting the technical solutions of the present disclosure. Although the present disclosure has been described in detail with reference to the aforementioned examples, those of ordinary skill in the art should understand that it is still possible to make modifications to the technical solutions described in the aforementioned examples or make equivalent substitutions to some or all of the technical features, and these modifications or equivalent substitutions do not deviate the essence of the corresponding technical solutions from the scope of the technical solutions of the examples of the present disclosure.

1. A preparation method for a diffractive optical waveguide, comprising:
providing a waveguide substrate;
forming a graphical imprinting adhesive layer on a surface of the waveguide substrate; the graphical imprinting adhesive layer comprises a first graphical imprinting structure and a second graphical imprinting structure; the first graphical imprinting structure is formed in a first region of the surface, and the second graphical imprinting structure is formed in a second region of the surface; the second graphical imprinting structure has a thickness greater than that of the first graphical imprinting structure;
performing first-stage etching on the waveguide substrate by using the graphical imprinting adhesive layer as a first mask, so as to form a coupling-in structure on the waveguide substrate in the first region, while the remaining graphical imprinting adhesive layer on the waveguide substrate in the second region maintains a pattern of the second graphical imprinting structure;
forming a second mask by using the remaining graphical imprinting adhesive layer, and performing a second-stage etching on the waveguide substrate based on the second mask, so as to form a coupling-out structure in the second region;
wherein the second mask covers the coupling-in structure to protect the coupling-in structure from being etched during the second-stage etching; the coupling-in structure and the coupling-out structure differ in structural morphology, and the coupling-out structure has a depth greater than that of the coupling-in structure.

2. The preparation method for the diffractive optical waveguide according to claim 1, wherein the coupling-out structure has an equal etching depth, or different regions of the coupling-out structure are not equal in the etching depth.

3. The preparation method for the diffractive optical waveguide according to claim 1, wherein forming a second mask by using the remaining graphical imprinting adhesive layer, and performing second-stage etching on the waveguide substrate based on the second mask, so as to form a coupling-out structure in the second region comprises:
forming a first hard mask layer; the first hard mask layer is formed on a surface of the waveguide substrate, and covers the coupling-in structure and the remaining graphical imprinting adhesive layer;
removing the remaining graphical imprinting adhesive layer and the first hard mask layer covering the remaining graphical imprinting adhesive layer to form the second mask;
performing a second-stage etching on the waveguide substrate by using the second mask as a mask, so as to form a coupling-out structure in the second region.

4. The preparation method for the diffractive optical waveguide according to claim 3, wherein performing second-stage etching on the waveguide substrate by using the second mask as a mask, so as to form a coupling-out structure in the second region comprises:
performing a first etching in the second-stage etching on the waveguide substrate by using the second mask as a mask, so as to form a coupling-out structure with an equal etching depth;
forming a photoresist layer N times; the photoresist layer formed each time covers a portion of the coupling-out structure, wherein N is an integer greater than or equal to 1;
etching, after each formation of the photoresist layer, a portion of the coupling-out structure that is not covered by the photoresist layer this time by using the photoresist layer formed this time and the remaining graphical imprinting adhesive layer as a mask, and forming the coupling-out structure in N+1 different etched regions after the Nth etching;
removing the photoresist layer and the second mask.

5. The preparation method for the diffractive optical waveguide according to claim 1, wherein forming a second mask by using the remaining graphical imprinting adhesive layer, and performing second-stage etching on the waveguide substrate based on the second mask, so as to form a coupling-out structure in the second region comprises:
forming a coupling-in protective layer on a surface of the coupling-in structure;
using the coupling-in protective layer and the remaining graphical imprinting adhesive layer as a second mask, and performing a second-stage etching on the waveguide substrate based on the second mask, so as to form a coupling-out structure in the second region.

6. The preparation method for the diffractive optical waveguide according to claim 5, wherein forming a coupling-in protective layer on a surface of the coupling-in structure comprises:
dropping a predetermined amount of photoresist in a region where the coupling-in structure is located;
making the photoresist flow uniformly and cover a surface of the coupling-in structure under vacuum and negative pressure conditions;
curing the photoresist to form the photoresist layer.

7. The preparation method for the diffractive optical waveguide according to claim 5, wherein the coupling-in protective layer has a thickness greater than that of the remaining graphical imprinting adhesive layer.

8. The preparation method for the diffractive optical waveguide according to claim 1, wherein forming a graphical imprinting adhesive layer on a surface of the waveguide substrate specifically comprises:
providing an imprinting master; wherein the imprinting master is provided with a first master graphical structure and a second master graphical structure; wherein the first master graphical structure corresponds to the coupling-in structure; the second master graphical structure corresponds to the coupling-out structure;
coating the waveguide substrate with an imprinting adhesive;
imprinting the imprinting master onto the imprinting adhesive to form the graphical imprinting adhesive layer; wherein the graphical imprinting adhesive layer has a pattern corresponding to patterns of the first master graphical structure and the second master graphical structure;
separating the imprinting master from the graphical imprinting adhesive layer.

9. The preparation method for the diffractive optical waveguide according to claim 8, wherein imprinting the imprinting master onto the imprinting adhesive to form the graphical imprinting adhesive layer specifically comprises:
imprinting the imprinting master onto the imprinting adhesive;
curing the imprinting adhesive to form the graphical imprinting adhesive layer.

10. The preparation method for the diffractive optical waveguide according to claim 8, wherein the imprinting adhesive has a thickness adapted to the maximum depth of the patterns in the first master graphical structure and the second master graphical structure.

11. A diffractive optical waveguide, which is produced by the preparation method for the diffractive optical waveguide according to claim 1.

12. An imprinting master, applied to the preparation method for the diffractive optical waveguide according to claim 1, comprising:
a substrate;
a first master graphical structure and a second master graphical structure, which are formed on the substrate; wherein the substrate at the second master graphical structure has a thickness less than that of the substrate at the first master graphical structure;
the imprinting master is used to prepare a diffractive optical waveguide; the second master graphical structure has a pattern matching that of a coupling-out structure of the diffractive optical waveguide; the first master graphical structure has a pattern matching that of a coupling-in structure of the diffractive optical waveguide.

13. The imprinting master according to claim 12, wherein the second master graphical structure comprises a number of groove structures or a number of protruding structures.

14. The imprinting master according to claim 13, wherein the groove structure comprised in the second master graphical structure has a uniform depth.

15. The imprinting master according to claim 13, wherein the second master graphical structure is a straight-tooth structure.

16. The imprinting master according to claim 13, wherein the groove structure comprised in the second master graphical structure has a position consistent with that of a groove of the coupling-out structure of the diffractive optical waveguide; the groove structure comprised in the second master graphical structure has a width consistent with that of the groove of the coupling-out structure of the diffractive optical waveguide.

17. The imprinting master according to claim 12, wherein the first master graphical structure is a blazed structure.

18. The imprinting master according to claim 12, wherein the imprinting master has a material of SiO₂, Si, quartz glass, or high-refractive glass.

19. The imprinting master according to claim 12, wherein the second master graphical structure and/or the first master graphical structure has a closed shape surrounded by a curve and/or straight line.

20. The imprinting master according to claim 12, wherein the first master graphical structure has a pattern complementary to that of the coupling-in structure of the diffractive optical waveguide.
